(19) United States
(12) Patent Application Publication
(10) Pub. No.: US 2026/0197581 A1
(43) Pub. Date: Jul. 9, 2026

(54) AUDIO DRIVER INCLUDING CLICK-AND-POP REDUCTION CIRCUIT DUE TO H-Y BRIDGE TRANSITIONS

(71) Applicant: QUALCOMM Incorporated, San Diego, CA (US)

(72) Inventors: Lei SUN, San Diego, CA (US); Dongyang TANG, San Diego, CA (US); Sherif GALAL, Irvine, CA (US)

(21) Appl. No.: 19/009,651

(22) Filed: Jan. 3, 2025

(51) Int. Cl. H04R 3/02; H03F 3/183

(52) U.S. Cl. CPC H04R 3/02; H03F 3/183; H03F 2200/03

(57) ABSTRACT

An audio driver including: a first common mode voltage circuit configured to generate a first common mode voltage based on a selected one of a first supply voltage or a second supply voltage, wherein the first supply voltage is greater than the second supply voltage, wherein the first common mode voltage exhibits a voltage change in response to switching between the first supply voltage and the second supply voltage; a first integrator configured to integrate a first difference between a first integrator input signal and the first common mode voltage to generate a first integrator output signal, wherein an audio signal is based on the first integrator output signal, wherein the first integrator output signal exhibits a first artifact in response to the voltage change in the first common mode voltage; and an artifact reduction circuit configured to reduce an effect on the audio signal due to the first artifact.

### FIELD

This disclosure relates generally to audio drivers, and in particular, to an audio driver including a click and pop reduction circuit to reduce clicks and pops produced by a speaker as a result of signal artifacts due to H-Y bridge transitions.

### BACKGROUND

An audio driver receives an input audio signal and generates therefrom an output audio signal to drive a speaker. The speaker may be driven by a power stage including an H-bridge and a Y-bridge. The H-bridge provides a higher power audio signal to the speaker based on a higher supply voltage when the input audio signal is relatively large requiring the speaker to generate louder audio. The Y-bridge provides a lower power audio signal to the speaker based on a lower supply voltage when the input audio signal is relatively small causing the speaker to generate quieter audio. The Y-bridge is used for power savings. Switching between the H-bridge and the Y-bridge may cause audio signal artifacts, which may cause the speaker to produce audio clicks and pops.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an audio driver for generating an audio signal. The audio driver including: a first common mode voltage circuit configured to generate a first common mode voltage based on a selected one of a first supply voltage or a second supply voltage, wherein the first supply voltage is greater than the second supply voltage, wherein the first common mode voltage exhibits a voltage change in response to switching between the first supply voltage and the second supply voltage; a first integrator configured to integrate a first difference between a first integrator input signal and the first common mode voltage to generate a first integrator output signal, wherein the audio signal is based on the first integrator output signal, wherein the first integrator output signal exhibits a first artifact in response to the voltage change in the first common mode voltage; and an artifact reduction circuit configured to reduce an effect on the audio signal due to the first artifact.

Another aspect of the disclosure relates to a method of providing an audio signal to a speaker. The method includes: integrating a difference between a first integrator input signal and a first common mode voltage to generate a first integrator output signal, wherein the audio signal is based on the first integrator output signal; generating a voltage change in the first common mode voltage in response to a change between a first supply voltage and a second supply voltage, wherein the voltage change in the first common mode voltage produces a first artifact in the first integrator output signal; and reducing an effect on the audio signal due to the first artifact.

Another aspect of the disclosure relates to an apparatus. The apparatus, includes: a first integrator including a signal input, a common mode input, and an output; a second integrator including a signal input, a common mode input, and an output; a comparator including a first signal input coupled to the output of the first integrator, a second signal input coupled to the second output of the second integrator, and a common mode input; and a capacitor coupled to the common mode input of the comparator.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example audio driver in accordance with an aspect of the disclosure.

FIG. 1B illustrates a signal diagram of an example operation of the audio driver of FIG. 1A in accordance with another aspect of the disclosure.

FIG. 2 illustrates a schematic/block diagram of an example power stage in accordance with another aspect of the disclosure.

FIG. 3A illustrates a block diagram of another example audio driver in accordance with another aspect of the disclosure.

FIG. 3B illustrates a signal diagram of an example operation of the audio driver of FIG. 3A in accordance with another aspect of the disclosure.

FIG. 4A illustrates a block diagram of another example audio driver in accordance with another aspect of the disclosure.

FIG. 4B illustrates a signal diagram of an example operation of the audio driver of FIG. 4A in accordance with another aspect of the disclosure.

FIG. 5A illustrates a block diagram of another example audio driver in accordance with another aspect of the disclosure.

FIG. 5B illustrates a signal diagram of an example operation of the audio driver of FIG. 5A in accordance with another aspect of the disclosure.

FIG. 6 illustrates a block diagram of another example audio driver in accordance with another aspect of the disclosure.

FIG. 7 illustrates a flow diagram of an example method of receiving a radio frequency (RF) signal in with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

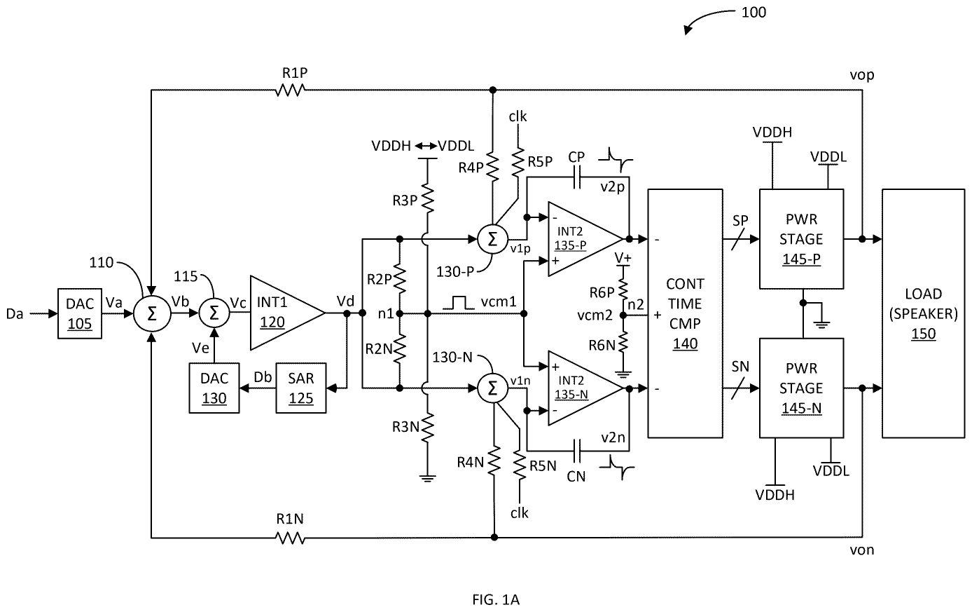

FIG. 1A illustrates a block diagram of an example audio driver 100 in accordance with an aspect of the disclosure. The audio driver 100 is configured to receive a digital audio signal Da and generate positive-side (P-side) output audio signal vop and negative-side (N-side) output audio signal von for driving a load 150, such as a speaker. The audio driver 100 includes digital-to-analog converters (DACs) 105 and 130, voltage summers (Σ) 110, 115, 130-P, and 130-N, integrator amplifiers 120, 135-P, and 135-N, successive approximation register (SAR) 125, resistors R1P/R1N to R6P/R6N, capacitors CP and CN, a continuous time comparator 140, and power stages 145-P and 145-N.

The DAC 105 is configured to receive and convert the digital audio signal Da (e.g., from an audio codec) into an analog audio signal Va generated at an output thereof. The first summer 110 includes a first input coupled to the output of the DAC 105 to receive the analog audio signal Va, a second input coupled to an output of the P-side power stage 145-P to receive the P-side output audio signal vop, and a third input coupled to an output of the N-side power stage 145-N to receive the N-side output signal von. The first summer 110 is configured to combine the analog audio signal Va with the P-side and N-side output signals vop/von to generate a second analog signal Vb at an output thereof.

The second summer 115 includes a first input coupled to the output of the first summer 110 to receive the second analog signal Vb, and a second input coupled to an output of the DAC 130 to receive an analog feedback signal Ve. The second summer 115 is configured to combine the second analog signal Vb with the analog feedback signal Ve to generate a third audio signal Vc at an output thereof. The first integrator amplifier (INT1) 120 includes an input coupled to the output of the second summer 115 to receive the third audio signal Vc. The first integrator amplifier 120 is configured to generate a fourth audio signal Vd at an output thereof. The SAR 125 includes an input coupled to the output of the first integrator amplifier 120 to receive the fourth audio signal Vd. The SAR 125 is configured to digitize the fourth audio signal Vd to generate a digital feedback signal Db at an output thereof. The DAC 130 includes an input coupled to the output of the SAR 125 to receive the digital feedback signal Db. The DAC 125 is configured to convert the digital feedback signal Db into the analog feedback signal Ve. The first integrator amplifier 120, SAR 125, second DAC 130, and second summer 115 collectively integrate the second audio signal Vb to generate the fourth audio signal Vd.

The resistors R2P/R2N are coupled between the output of the first integrator amplifier 120 and a common mode node n1. The resistors R3P/R3N are coupled between a mode selected one of a higher upper voltage rail VDDH or a lower upper voltage rail VDDL and a lower voltage rail (e.g., ground). The resistors R2P/R2N and/or R3P/R3N, collectively a first common mode voltage circuit, generate a first common mode voltage vcm1 at the common mode node n1.

The third P-side summer 130-P includes a first input coupled to the output of the first integrator amplifier 120 to receive the fourth audio signal Vd. The third P-side summer 130-P includes a second input coupled to the output of the P-side power stage 145-P via the resistor R4P to receive the P-side output audio signal vop. The third P-side summer 130-P includes a third input configured to receive a clock signal clk via the resistor R5P. The third P-side summer 130-P is configured to combine the fourth audio signal Vd, the P-side output audio signal vop, and the clock signal clk to generate a P-side integrator input signal v1p at an output thereof.

The third N-side summer 130-N includes a first input coupled to the output of the first integrator amplifier 120 to receive the fourth audio signal Vd. The third N-side summer 130-N includes a second input coupled to the output of the N-side power stage 145-N via the resistor R4N to receive the N-side output audio signal von. The third N-side summer 130-N includes a third input configured to receive the clock signal clk via the resistor R5N. The third N-side summer 130-N is configured to combine the fourth audio signal Vd, the N-side output audio signal von, and the clock signal clk to generate an N-side integrator input signal v1n at an output thereof.

The P-side integrator amplifier (INT2) 135-P includes a first (e.g., negative) input coupled to the output of the third P-side summer 130-P to receive the P-side integrator input signal v1p. The P-side capacitor CP is coupled between an output of the P-side second integrator amplifier 135-P and the first input of the second P-side integrator amplifier 135-P. The P-side integrator amplifier (INT2) 135-P includes a second (e.g., positive) input coupled to the first common mode node n1 to receive the first common mode voltage Vcm1. The P-side integrator amplifier 135-P and the P-side capacitor CP are collectively configured to integrate a difference between the P-side integrator input signal v1p and the first common mode voltage signal vcm1 to generate a P-side integrator output signal v2p.

The N-side integrator amplifier (INT2) 135-N includes a first (e.g., negative) input coupled to the output of the third N-side summer 130-N to receive the N-side integrator signal v1n. The N-side capacitor CN is coupled between an output of the N-side integrator amplifier (INT2) 135-N and the first input of the second N-side integrator amplifier 135-N. The N-side integrator amplifier (INT2) 135-N includes a second (e.g., positive) input coupled to the first common mode node n1 to receive the first common mode voltage Vcm1. The N-side integrator amplifier 135-N and the N-side capacitor CN are collectively configured to integrate a difference between the N-side integrator input signal v1n and the first common mode voltage signal to generate an N-side integrator output signal v2n.

The continuous time comparator 140 includes a P-side (e.g., negative) input coupled to the output of the P-side integrator amplifier 135-P to receive the P-side integrator output signal v2p. The continuous time comparator 140 includes an N-side (e.g., negative) input coupled to the output of the N-side integrator amplifier 135-N to receive the N-side integrator output signal v2n. The resistors R6P and R6N, serving as a second common mode voltage circuit, are coupled between an upper voltage rail V+ and a negative voltage rail (e.g., ground) to generate a second common mode voltage vcm2 at a second common mode node n2 (between the resistors R6P and R6N) coupled to a common mode input (+) of the continuous time comparator 140. The continuous time comparator 140 is configured to generate a P-side pulse width modulated signal SP at an output thereof based on a difference between the P-side integrator output signal v2p and the second common mode voltage vcm2. The continuous time comparator 140 includes an N-side output configured to generate an N-side pulse width modulated SN at an N-side output thereof based on a difference between the N-side integrator output signal v2n and the second common mode voltage vcm2.

The P-side power stage 145-P includes an input coupled to the P-side output of the continuous time comparator 140 to receive the P-side pulse width modulated signal SP, a first power rail port configured to receive a higher upper supply voltage VDDH, a second power rail port configured to receive a lower (power saving) upper supply voltage VDDL, and a third power rail port coupled to a lower voltage rail (e.g., ground). The P-side power stage 145-P is configured to generate the P-side output audio signal vop at an output thereof based on the P-side pulse width modulated signal SP.

The N-side power stage 145-N includes an input coupled to the N-side output of the continuous time comparator 140 to receive the N-side pulse width modulated signal SN, a first power rail port configured to receive the higher upper supply voltage VDDH, a second power rail port configured to receive the lower (power saving) upper supply voltage VDDL, and a third power rail port coupled to the lower voltage rail (e.g., ground). The N-side power stage 145-N is configured to generate the N-side output audio signal von at an output thereof based on the N-side pre-driver signal SN.

The load (e.g., speaker) 150 includes a first port coupled to the output of the P-side power stage 145-P to receive the P-side output audio signal vop. The load (e.g., speaker) 150 includes a second port coupled to the output of the N-side power stage 145-N to receive the N-side output audio signal von.

In operation, in high power mode (e.g., when the input audio signal Da has a power level above a threshold), the power stages 145-P and 145-N use the higher upper supply voltage VDDH to generate the output audio signals vop and von for driving the load 150. In low power mode (e.g., when the input audio signal Da has a power level below the threshold), the power stages 145-P and 145-N use the lower upper supply voltage VDDL to generate the output audio signals vop and von for driving the load 150, respectively.

As the first common mode voltage circuit R3P/R3N is coupled between the selected higher upper power supply rail VDDH in high power mode or the selected lower upper voltage rail VDDL in low power mode, and the lower voltage rail (e.g., ground), the first common mode voltage vcm1 exhibits an increase voltage change or a decrease voltage change in response to changing to the high power mode (VDDH) or to low power mode (VDDL), respectively. This is graphically indicated in the diagram as a voltage change. As the first common mode voltage vcm1 is provided to the second (e.g., positive) inputs of the second integrator amplifiers 135-P and 135-N, the second integrators 135-P/CP and 135-N/CN integrate the voltage change in the first common mode voltage vcm1 to generate artifacts in the form of positive and negative spikes in the P-side and N-side integrator output signals v2p and v2n, respectively. These artifacts effect the output audio signals vop/von, which may cause the load (e.g., speaker) 150 to generate audio clicks and pops, which may be undesirable.

FIG. 1B illustrates a signal diagram of an example operation of the audio driver 100 in accordance with another aspect of the disclosure. The horizontal axis represents time. The vertical axis, from top to bottom, represents the state of the power mode, the first common mode voltage vcm1, and the integrator output signals v2p/v2n of the second integrators 135-P/CP and 135-N/CN. As shown, when the power mode transitions from the low power mode (VDDL) to the high power mode (VDDH), the first common mode voltage vcm1 exhibits a voltage change including a rising transition. The second integrators 135-P/CP and 135-N/CN integrate the rising transition to generate a positive spike artifact in the integrator output signals v2p/v2n. Similarly, when the power mode transitions from the higher upper supply voltage VDDH to the lower upper supply voltage VDDL, the first common mode voltage vcm1 exhibits a voltage change including a falling transition. The second integrators 135-P/CP and 135-N/CN integrate the falling transition to generate a negative spike artifact in the integrator output signals v2p/v2n. As discussed, these artifacts cause the load (e.g., speaker) 150 to generate audio clicks and pops.

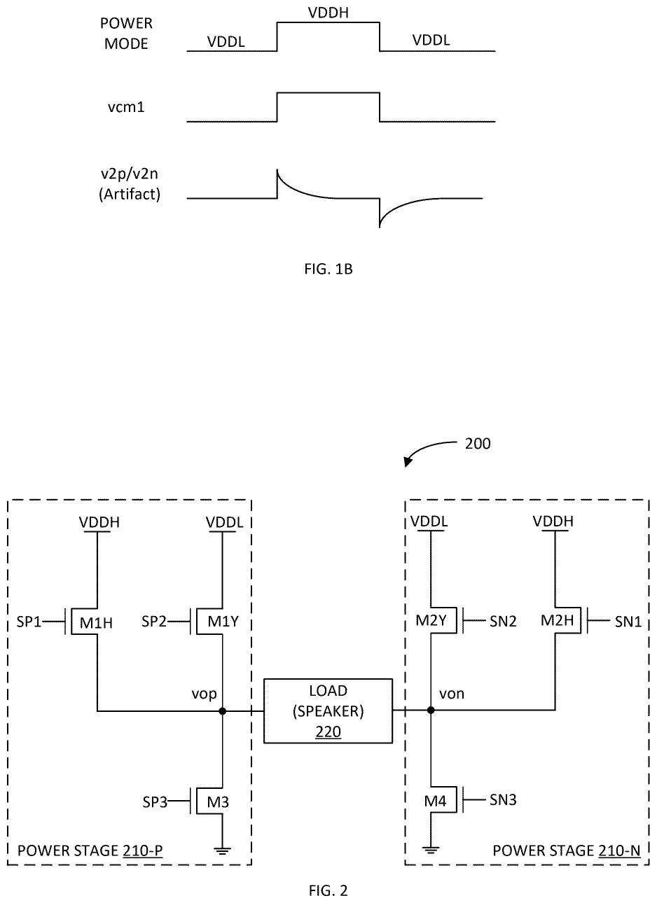

FIG. 2 illustrates a schematic/block diagram of an example power stage 200 in accordance with another aspect of the disclosure. The power stage 200 includes a P-side power stage 210-P and an N-side power stage 210-N. The P-side power stage 210-P and the N-side power stage 210-N are example implementations of the P-side power stage 145-P and the N-side power stage 145-N of the audio driver 100, respectively.

The P-side power stage 210-P includes a first switching device (e.g., field effect transistor (FET)) M1H, a second switching device (e.g., FET) M1Y, and a third switching device (e.g., FET) M3. The first switching device M1H is coupled between the higher upper voltage rail VDDH and a P-side output port (where the P-side output audio signal vop is generated). The first switching device M1H includes a control input (e.g., gate) configured to receive a pulse width modulated signal SP1 from the continuous time comparator 140. The second switching device M1Y is coupled between the lower upper voltage rail VDDL and the P-side output port. The second switching device M1Y includes a control input (e.g., gate) configured to receive a pulse width modulated signal SP2 from the continuous time comparator 140. The third switching device (e.g., FET) M3 is coupled between the P-side output port and a lower voltage rail (e.g., ground). The third switching device M3 includes a control input (e.g., gate) configured to receive a pulse width modulated signal SP3 from the continuous time comparator 140.

The N-side power stage 210-N includes a first switching device (e.g., FET) M2H, a second switching device (e.g., FET) M2Y, and a third switching device (e.g., FET) M4. The first switching device M2H is coupled between the higher upper voltage rail VDDH and an N-side output port (where the N-side output audio signal von is generated). The first switching device M2H includes a control input (e.g., gate) configured to receive a pulse width modulated signal SN1 from the continuous time comparator 140. The second switching device M2Y is coupled between the lower upper voltage rail VDDL and the N-side output port. The second switching device M2Y includes a control input (e.g., gate) configured to receive a pulse width modulated signal SN2 from the continuous time comparator 140. The third switching device (e.g., FET) M4 is coupled between the N-side output port and the lower voltage rail. The third switching device M4 includes a control input (e.g., gate) configured to receive a pulse width modulated signal SN3 from the continuous time comparator 140.

The load (e.g., speaker) 220 is coupled between the P-side output port and the N-side output port. The switching devices M1H and M2H are often referred to as the H-bridge. The switching devices M1Y and M2Y are referred to as the Y-bridge. Accordingly, in high power mode, the H-bridge is enabled and the Y-bridge is disabled. That is, in high power mode, the pulse width modulated signals SP1, SN3, SN1, and SP3 operate the switching devices M1H, M4, M2H, and M3 to deliver relatively high audio currents through the load (e.g., speaker) 220, and the signals SP2 and SN2 turn off the switching devices M1Y and M2Y, respectively. In low power mode, the pulse width modulated signals SP2, SN3, SN2, and SP3 operate the switching devices M1Y, M4, M2Y, and M3 to deliver relatively low audio currents through the load (e.g., speaker) 220, and the signals SP1 and SN1 turn off the switching devices M1H and M2H, respectively.

In operation, during a positive cycle of the high power mode operation, the pulse width modulated signals SP1 and SN3 turn on the switching devices M1H and M4, and the pulse width modulated signals SN1 and SP3 turn off the switching devices M2H and M3. Accordingly, an audio current signal flows from the higher upper voltage rail VDDH to the lower voltage rail (e.g., ground) via the switching device M1H, the load (e.g., speaker) 220, and the switching device M4 (e.g., from left-to-right across the load 220). During a negative cycle of the high power mode operation, the pulse width modulated signals SN1 and SP3 turn on the switching devices M2H and M3, and the pulse width modulated signals SP1 and SN3 turn off the switching devices M1H and M4. Accordingly, an audio current signal flows from the higher upper voltage rail VDDH to the lower voltage rail (e.g., ground) via the switching device M2H, the load (e.g., speaker) 220, and the switching device M3 (e.g., from right-to-left across the load 220).

During a positive cycle of the low power mode operation, the pulse width modulated signals SP2 and SN3 turn on the switching devices M1Y and M4, and the pulse width modulated signals SN2 and SP3 turn off the switching devices M2Y and M3. Accordingly, an audio current signal flows from the lower upper voltage rail VDDL to the lower voltage rail (e.g., ground) via the switching device M1Y, the load (e.g., speaker) 220, and the switching device M4 (e.g., from left-to-right across the load 220). During a negative cycle of the low power mode operation, the pulse width modulated signals SN2 and SP3 turn on the switching devices M2Y and M3, and the pulse width modulated signals SP2 and SN3 turn off the switching devices M1Y and M4. Accordingly, an audio current signal flows from the lower upper voltage rail VDDL to the lower voltage rail (e.g., ground) via the switching device M2Y, the load (e.g., speaker) 220, and the switching device M3 (e.g., from right-to-left across the load 220).

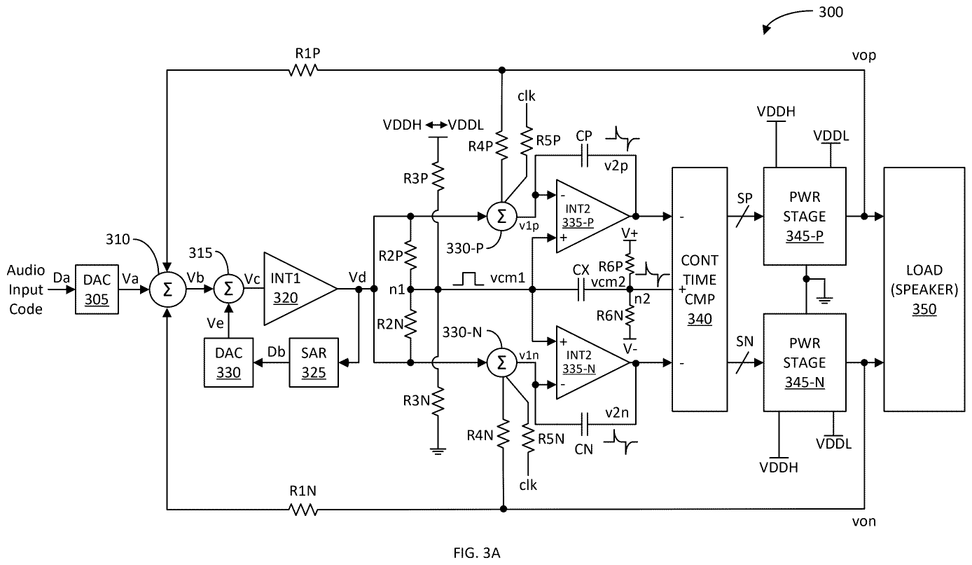

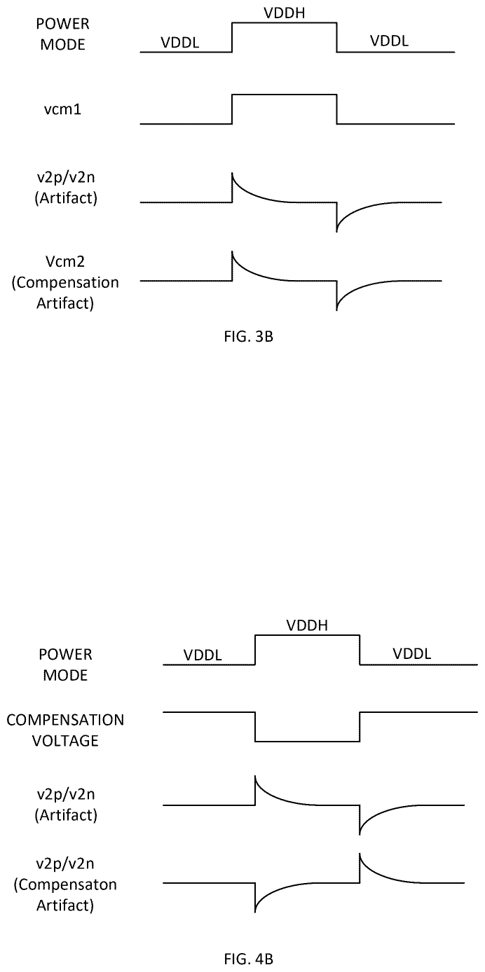

FIG. 3A illustrates a block diagram of another example audio driver 300 in accordance with another aspect of the disclosure. As discussed further herein, the audio driver 300 includes artifact reduction circuit (e.g., a capacitor CX) to reduce audio clicks and pops as a result of changing between high power mode and low power mode. The audio driver 300 is similar to audio driver 100 including many of the same elements as indicated by the same reference identifiers and numbers with the exception that the most significant digit in the reference numbers is a “3” for elements in audio driver 300 instead of “1” for corresponding elements in audio driver 100.

The audio driver 300 further includes a capacitor CX coupled between the first common mode node n1 and the second common mode node n2, which is coupled to the common mode input (+) of the continuous time comparator 340. The capacitor CX integrates the voltage change generated at the first common mode voltage vcm1 due to changing between high power mode (VDDH) and low power mode (VDDL) to generate a compensation artifact in the second common mode voltage vcm2. The capacitor CX may have substantially the same capacitance as each of the capacitors CP and CN. The compensation artifact is substantially the same as the artifacts produced in the integrator output signals v2p and v2n.

As the continuous time comparator 340 generates the pulse width modulated signals SP and SN based on respective differences between the integrator output signals v2p and v2n and the second common mode voltage vcm2 (e.g., SP~(v2p−vcm2) and SN~(v2n−vcm2)), the artifact and compensation artifact being respectively both v2p and vcm2 at least partially cancels each other out in the generation of the P-side pulse width modulated signal SP, and respectively in both v2n and vcm2 at least partially cancels each other out in the generation of the N-side pulse width modulated signal SN. Thus, this reduces and/or eliminates the effects of the artifacts in the output audio signals vop/von to reduce and/or eliminate audio clicks and pops produced by the load (e.g., speaker) 350 due to transitions between high power mode (VDDH) and low power mode (VDDL).

FIG. 3B illustrates a signal diagram of an example operation of the audio driver 300 in accordance with another aspect of the disclosure. The horizontal axis represents time. The vertical axis, from top to bottom, represents the state of the power mode, the first common mode voltage vcm1, the integrator output signals v2p/v2n of the second integrators 135-P/CP and 135-N/CN, and the second common mode voltage vcm2. As shown, when the power mode transitions from the low power mode (VDDL) to the high power mode (VDDH), the first common mode voltage vcm1 exhibits a voltage change including a rising transition. The second integrators 135-P/CP and 135-N/CN integrate the rising transition to generate a positive spike artifact in the integrator output signals v2p/v2n. The capacitor CX also integrates the rising transition to generate a positive spike compensation artifact in the second common mode voltage vcm2. As the continuous time comparator 340 generates the pulse width modulated signals SP and SN based on v2p−vcm2 and v2n−vcm2, the artifacts are cancelled out in the generation of the pulse width modulated signals SP and SN.

Similarly, when the power mode transitions from the higher upper supply voltage VDDH to the lower upper supply voltage VDDL, the first common mode voltage vcm1 exhibits a voltage change including a falling transition. The second integrators 135-P/CP and 135-N/CN integrate the falling transition to generate a negative spike artifact in the integrator output signals v2p/v2n. The capacitor CX also integrates the falling transition to generate a negative compensation spike artifact in the second common mode voltage vcm2. As the continuous time comparator 340 generates the pulse width modulated signals SP and SN based on v2p−vcm2 and v2n−vcm2, the artifacts are cancelled out in the generation of the pulse width modulated signals SP and SN.

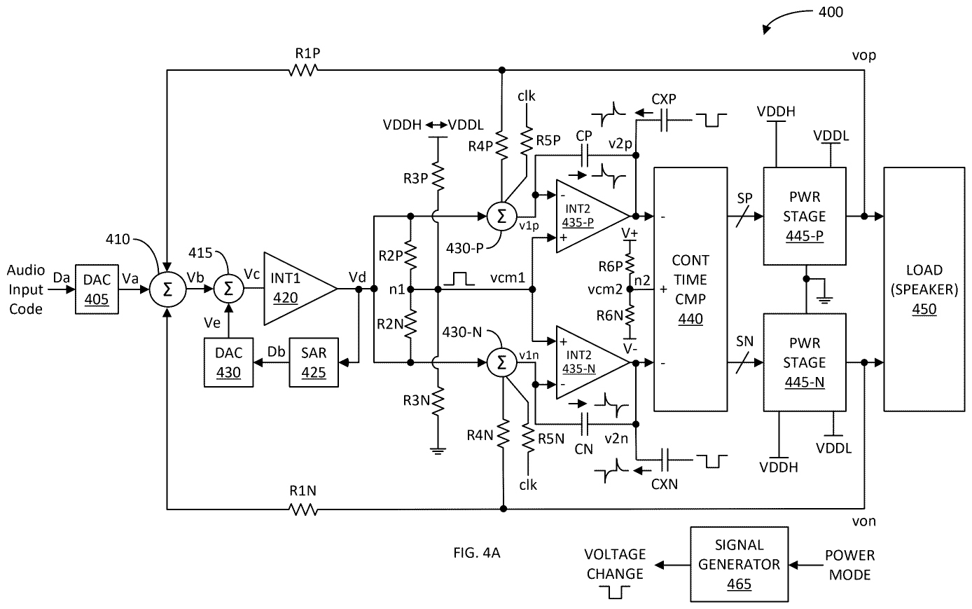

FIG. 4A illustrates a block diagram of another example audio driver 400 in accordance with another aspect of the disclosure. As discussed further herein, the audio driver 400 includes an artifact reduction circuit (e.g., signal generator 465 and capacitors CXP/CNX) to reduce audio clicks and pops as a result of changing between high power mode and low power mode. The audio driver 400 is similar to audio driver 100 including many of the same elements as indicated by the same reference identifiers and numbers with the exception that the most significant digit is a “4” in the reference numbers for elements in audio driver 400 instead of “1” for corresponding elements in audio driver 100.

The audio driver 400 further includes a signal generator 465, a P-side capacitor CXP, and an N-side capacitor CXN. The signal generator 465 is configured to generate a compensation voltage change substantially coincidental with and opposite to the voltage change generated in the first common mode voltage vcm1 in response to changing between high power mode and low power mode. The P-side capacitor CXP is coupled between the output of the signal generator 465 and the output of the P-side second integrator amplifier 435-P. Similarly, the N-side capacitor CXN is coupled between the output of the signal generator 465 and the output of the N-side second integrator amplifier 435-N.

When the power mode transitions from the low power mode (VDDL) to the high power mode (VDDH), the first common mode voltage vcm1 exhibits a voltage change including a rising transition. Also, in response to the low power mode (VDDL) to the high power mode (VDDH) transition, the signal generator 465 generates a compensation voltage change including a falling transition substantially coincidental with the rising transition in the first common mode voltage vcm1. The second integrators 135-P/CP and 135-N/CN integrate the rising transition to generate a positive spike artifact in the integrator output signals v2p/v2n. The capacitors CXP and CNN integrate the (compensation) falling transition to generate a negative spike compensation artifact in the integrator output signals v2p/v2n. The negative spike compensation artifact at least partially cancels out the positive spike artifacts generated by the integrators 435-P/435-N. Thus, this reduces and/or eliminates the effect on the output audio signals vop/von to reduce audio clicks and pops produced by the load (e.g., speaker 450).

Similarly, when the power mode transitions from the high power mode (VDDH) to the low power mode (VDDL), the first common mode voltage vcm1 exhibits a voltage change including a falling transition. Also, in response to the high power mode (VDDH) to the low power mode (VDDL) transition, the signal generator 465 generates a compensation voltage change including a rising transition substantially coincidental with the falling transition in the first common mode voltage vcm1. The second integrators 135-P/CP and 135-N/CN integrate the falling transition to generate a negative spike artifact in the integrator output signals v2p/v2n. The capacitors CXP and CNN integrate the (compensation) rising transition to generate a positive spike compensation artifact in the integrator output signals v2p/v2n. The positive spike compensation artifacts at least partially cancel out the negative spike artifacts generated by the integrators 435-P/435-N. Thus, this reduces and/or eliminates the effect on the output audio signals vop/von to reduce audio clicks and pops produced by the load (e.g., speaker 450) due to transitions between the high power mode and the low power mode.

FIG. 4B illustrates a signal diagram of an example operation of the audio driver 400 in accordance with another aspect of the disclosure. The horizontal axis represents time. The vertical axis, from top to bottom, represents the state of the power mode, the compensation voltage change generated by the signal generator 465, the uncompensated integrator output signals v2p/v2n, and the compensation integrator output signals v2p/v2n due to the signal generator 465 and capacitors CXP/CXN. As shown, when the power mode transitions from the low power mode (VDDL) to the high power mode (VDDH), the uncompensated integrator output signals v2p/v2n exhibits a positive spike artifact due to the voltage change in the first common mode voltage vcm1. Also, when the compensation voltage exbibits a falling transition, the compensation integrator output signals v2p/v2n exhibits a negative spike compensation artifact. The negative spike compensation artifact at least partially cancels out the positive spike artifacts in the compensated integrator output signals v2p/v2n. Similarly, when the power mode transitions from the high power mode (VDDH) to the low power mode (VDDL), the uncompensated integrator output signals v2p/v2n exhibits a negative spike artifact. When the compensation voltage exhibits a rising transition, the compensation integrator output signals v2p/v2n exhibit a positive spike compensation artifact. The positive spike artifact at least partially cancels out the negative spike artifacts in the compensated integrator output signals v2p/v2n.

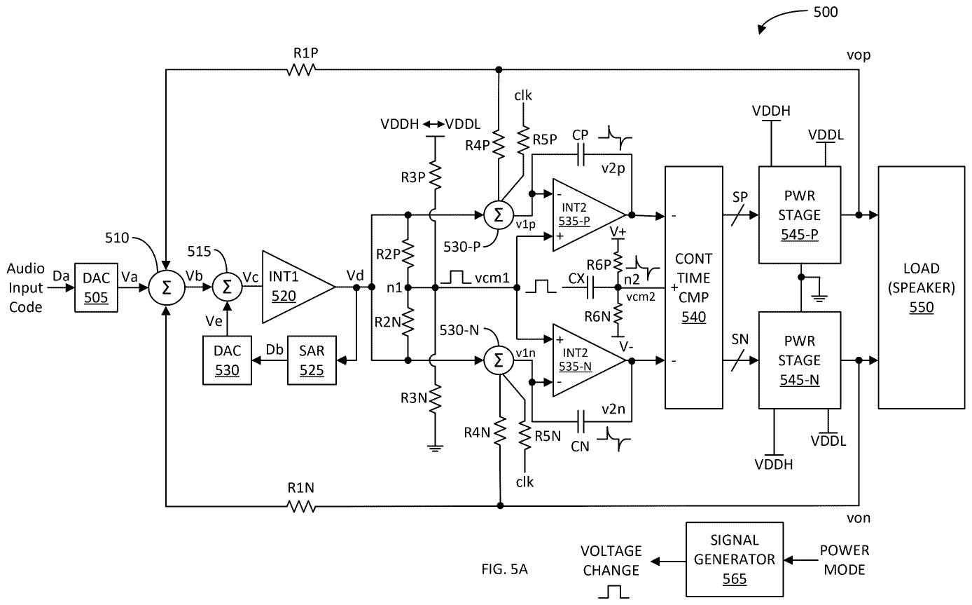

FIG. 5A illustrates a block diagram of another example audio driver 500 in accordance with another aspect of the disclosure. As discussed further herein, the audio driver 500 includes an artifact reduction circuit (e.g., signal generator 565 and capacitor CX) to reduce audio clicks and pops as a result of changing between high power mode and low power mode. The audio driver 500 is similar to audio driver 100 including many of the same elements as indicated by the same reference identifiers and numbers with the exception that the most significant digit is a “5” in the reference numbers for elements in audio driver 500 instead of “1” for corresponding elements in audio driver 100.

The audio driver 500 further includes a signal generator 565 and a capacitor CX. The signal generator 565 is configured to generate a compensation voltage change in the second common mode voltage vcm2. The compensation voltage change may be substantially coincidental with and the same as the voltage change generated in the first common mode voltage vcm1 in response to changing between high power mode and low power mode. The capacitor CX is coupled between the output of the signal generator 565 and the common mode voltage input (+) of the continuous time comparator 540. The capacitor CX may have substantially the same capacitance as each of the capacitor CP and CN. The capacitor CX integrates the compensation voltage change by the signal generator 565 to generate a compensation artifact in the second common mode voltage vcm2 being substantially the same as the artifacts in the second integrator output signals vop/von.

As the continuous time comparator 540 generates the pulse width modulated signals SP and SN based on respective differences between the integrator output signals v2p and v2n and the second common mode voltage vcm2 (e.g., SP~(v2p−vcm2) and SN~(v2n−vcm2)), the artifact and compensation artifact being respectively in both v2p and vcm2 at least partially cancels each other out in the generation of the P-side pulse width modulated signal SP, and being respectively in both v2n and vcm2 at least partially cancels each other out in the generation of the N-side pulse width modulated signal SN. Thus, this reduces and/or eliminates of the artifacts in the output audio signal vop/von so as to reduce audio clicks and pops produced by the load (e.g., speaker) due to transitions between the high power mode and the low power mode.

FIG. 5B illustrates a signal diagram of an example operation of the audio driver 500 in accordance with another aspect of the disclosure. The horizontal axis represents time. The vertical axis, from top to bottom, represents the state of the power mode, the compensation voltage generated by the signal generator 565, the integrator output signals v2p/v2n, and the second common mode voltage vcm2 due to the signal generator 565 and capacitor CX. As shown, when the power mode transitions from the low power mode (VDDL) to the high power mode (VDDH), the integrator output signals v2p/v2n exhibits a positive spike artifact. Also, when the compensation voltage exbibits a coincidental rising transition, the second common mode voltage vcm2 exhibit a positive spike compensation artifact. As the continuous time comparator 540 generates the pulse width modulated signals SP and SN based on respective differences between the integrator output signals v2p and v2n and the second common mode voltage vcm2 (e.g., SP~(v2p−vcm2) and SN~(v2n−vcm2)), artifacts and compensation artifacts at least partially cancel out in the generation of the pulse width modulated signals SP and SN, respectively.

When the power mode transitions from the high power mode (VDDH) to the low power mode (VDDL), the integrator output signals v2p/v2n exhibits a negative spike artifact. Also, when the compensation pulse exbibits a coincidental falling transition, the second common mode voltage vcm2 exhibit a negative spike compensation artifact. As the continuous time comparator 540 generates the pulse width modulated signals SP and SN based on respective differences between the integrator output signals v2p and v2n and the second common mode voltage vcm2 (e.g., SP~(v2p−vcm2) and SN~(v2n−vcm2)), artifacts and compensation artifacts at least partially cancel out in the generation of the pulse width modulated signals SP and SN, respectively.

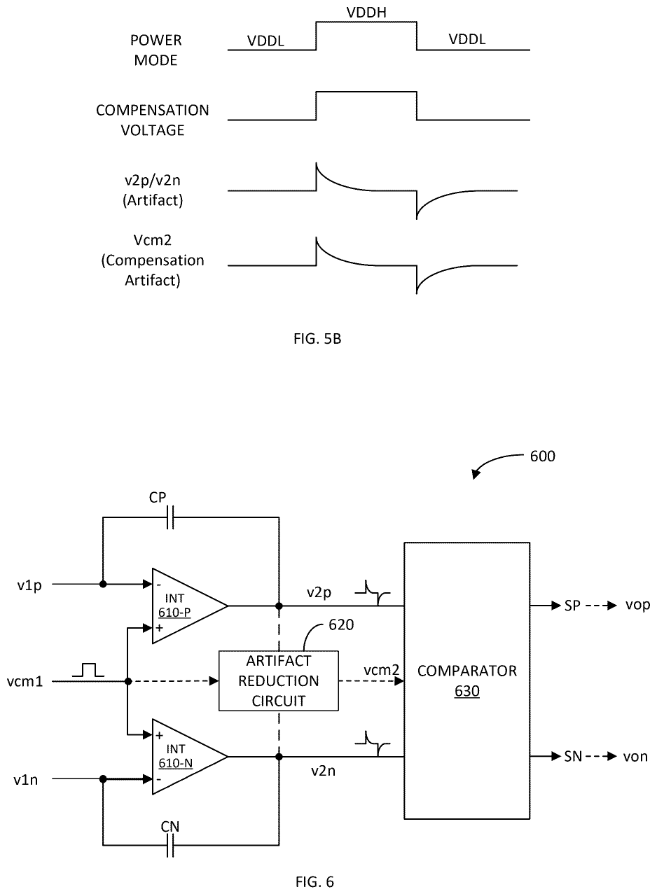

FIG. 6 illustrates a block diagram of another example audio driver 600 in accordance with another aspect of the disclosure. The audio driver 600 includes a first integrator 610-P including a first integrator amplifier 610-P and a first capacitor CP coupled. The first capacitor CP is coupled between a first (e.g., negative) input and an output of the first integrator 610-P. The first (e.g., negative) input of the first integrator 610-P is configured to receive a first integrator input signal v1p. The first integrator 610-P includes a second (e.g., positive) input configured to receive a first common mode signal vcm1. The first integrator 610-P is configured to integrate a difference between the first input audio signal v1p and the first common mode voltage vcm1 to generate a first integrator output signal v2p.

The audio driver 600 includes a second integrator 610-N including a second integrator amplifier 610-N and a second capacitor CN. The capacitor CN is coupled between a first (e.g., negative) input and an output of the second integrator 610-N. The second integrator 610-N includes a second (e.g., positive) input configured to receive the first common mode signal vcm1. The first (e.g., negative) input of the second integrator 610-N is configured to receive a second integrator input signal v1n. The second integrator 610-N configured to integrate a difference between the second integrator input signal v1n and the first common mode voltage vcm1 to generate a second integrator output signal v2n.

The audio driver 600 includes an artifact reduction circuit 620 to reduce the effects of artifacts, generated in the first and second integrator output signals v2p and v2n due to a voltage change in the first common mode voltage vcm1 due to a change in power mode, on output audio signals vop/von so as to reduce or eliminate clicks and pops on sound produced by a speaker caused by the artifacts. The artifact reduction circuit 620 may generate a compensation artifact to reduce the effects of the artifacts in the output audio signals vop/von.

In one implementation, the artifact reduction circuit 620 includes a capacitor configured to integrate the voltage change in the first common mode voltage vcm1 to generate the compensation artifact at a second common mode voltage vcm2. A comparator 630 is configured to: (1) generate a first pulse width modulated signal SP based on a difference between the first integrator output signal v2p and the second common mode voltage vcm2; and generate a second pulse width modulated signal SN based on a difference between the second integrator output signal v2n and the second common mode voltage vcm2. As the artifacts are present in the first and second integrator output signals v2p/v2n, and the compensation artifact is present in the second common mode voltage vcm2, the compensation artifact at least partially cancels the artifacts in the generation of the first and second pulse width modulated signals SP/SN, and ultimately, in the output audio signals vop/von.

In another implementation, the artifact reduction circuit 620 includes a signal generator and first and second capacitors coupled between the signal generator and the outputs of the first and second integrators. The signal generator is configured to generate a compensation voltage change that is substantially coincidental with, and equal and opposite to the voltage change in the first common mode voltage vcm1. The first and second capacitors generate compensation artifacts in the integrator output signals v2p/v2n by integrating the compensation voltage change generated by the signal generator. The compensation artifacts at least reduce the artifacts in the integrator output signals v2p/v2n, and ultimately, in the output audio signals vop/von.

In yet another implementation, the artifact reduction circuit 620 includes a signal generator and a capacitor coupled between the signal generator and a common mode input of the comparator 630. The signal generator is configured to generate a compensation voltage change that is substantially coincidental with and the same as the voltage change in the first common mode voltage vcm1. The capacitor is configured to generate a compensation artifact by integrating the compensation voltage change. As discussed, the comparator 630 is configured to: (1) generate a first pulse width modulated signal SP based on a difference between the first integrator output signal v2p and the second common mode voltage vcm2; and generate a second pulse width modulated signal SN based on a difference between the second integrator output signal v2n and the second common mode voltage vcm2. As the artifacts are present in the first and second integrator output signals v2p/v2n, and the compensation artifact is present in the second common mode voltage vcm2, the compensation artifact at least partially cancels the artifacts in the generation of the first and second pulse width modulated signals SP/SN, and ultimately, in the output audio signals vop/von.

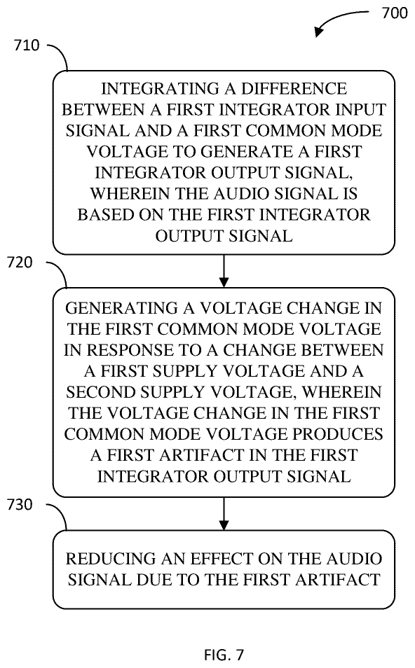

FIG. 7 illustrates a flow diagram of an example a method 700 of providing an audio signal to a speaker in accordance with another aspect of the disclosure. The method 700 includes: integrating a difference between a first integrator input signal and a first common mode voltage to generate a first integrator output signal, wherein the audio signal is based on the first integrator output signal (block 710). Examples of means for integrating a difference between a first integrator input signal and a first common mode voltage to generate a first integrator output signal include any of the integrators described herein.

The method 700 further includes generating a voltage change in the first common mode voltage in response to a change between a first supply voltage and a second supply voltage, wherein the voltage change in the first common mode voltage produces a first artifact in the first integrator output signal (block 720). Examples of means for generating a voltage change in the first common mode voltage in response to a change between a first supply voltage and a second supply voltage include any of the common mode voltage circuits with resistors R3P and R3N described herein.

Additionally, the method 700 includes reducing an effect on the audio signal due to the first artifact (block 730). Examples of means for reducing an effect on the audio signal due to the first artifact include any of the artifact reduction circuits (e.g., capacitor CX, signal generator 465 and capacitors CXP and CXN, and signal generator 565 and capacitor CX) described herein.

The following provides an overview of aspects of the present disclosure:
Aspect 1: An audio driver for generating an audio signal, comprising: a first common mode voltage circuit configured to generate a first common mode voltage based on a selected one of a first supply voltage or a second supply voltage, wherein the first supply voltage is greater than the second supply voltage, wherein the first common mode voltage exhibits a voltage change in response to switching between the first supply voltage and the second supply voltage; a first integrator configured to integrate a first difference between a first integrator input signal and the first common mode voltage to generate a first integrator output signal, wherein the audio signal is based on the first integrator output signal, wherein the first integrator output signal exhibits a first artifact in response to the voltage change in the first common mode voltage; and an artifact reduction circuit configured to reduce an effect on the audio signal due to the first artifact.
Aspect 2: The audio driver of aspect 1, wherein the artifact reduction circuit is configured to generate a first compensation artifact to reduce the first artifact.
Aspect 3: The audio driver of aspect 2, wherein: the first integrator comprises: a first integrator amplifier including a first input configured to receive the first integrator input signal, a second input configured to receive the first common mode voltage, and an output configured to generate the first integrator output signal; and a first capacitor coupled between the output and the first input of the first integrator amplifier; wherein the artifact reduction circuit comprises: a signal generator configured to generate a compensation voltage change substantially coincidental with and opposite to the voltage change in the first common mode voltage; and a second capacitor configured to generate the first compensation artifact at the output of the first integrator in response to the compensation voltage change.
Aspect 4: The audio driver of aspect 3, wherein the audio driver further comprises a second integrator configured to integrate a second difference between a second integrator input signal and the first common mode voltage to generate a second integrator output signal, wherein the audio signal is based on the second integrator output signal, wherein the second integrator output signal exhibits a second artifact in response to the voltage change in the first common mode voltage, wherein the artifact reduction circuit is configured to generate a second compensation artifact to reduce the second artifact.
Aspect 5: The audio driver of aspect 4, wherein the second integrator comprises: a second integrator amplifier including a first input configured to receive the second integrator input signal, a second input configured to receive the first common mode voltage, and an output configured to generate the second integrator output signal; and a third capacitor coupled between the output and the first input of the second integrator amplifier; wherein the artifact reduction circuit further comprises a fourth capacitor configured to generate the second compensation artifact at the output of the second integrator in response to the compensation voltage change.
Aspect 6: The audio driver of aspect 1, further comprising: a second common mode voltage circuit configured to generate a second common mode voltage; and a comparator configured to generate a first pulse width modulated signal based on a difference between the first integrator output signal and the second common mode voltage; wherein the artifact reduction circuit comprises a capacitor coupled between the first common mode voltage circuit and the second common mode voltage circuit, the capacitor configured to generate a compensation artifact in the second common mode voltage in response to the voltage change in the first common mode voltage.
Aspect 7: The audio driver of aspect 6, wherein the audio driver further comprises a second integrator configured to integrate a second difference between a second integrator input signal and the first common mode voltage to generate a second integrator output signal, wherein the second integrator output signal exhibits a second artifact in response to the voltage change in the first common mode voltage, wherein the comparator is configured to generate a second pulse width modulated signal based on a difference between the second integrator output signal and the second common mode voltage.
Aspect 8: The audio driver of aspect 1, further comprising: a second common mode voltage circuit configured to generate a second common mode voltage; and a comparator configured to generate a first pulse width modulated signal based on a difference between the first integrator output signal and the second common mode voltage; wherein the artifact reduction circuit comprises: a signal generator configured to generate a compensation voltage change substantially coincidental with and the same as the voltage change in the first common mode voltage; and a capacitor coupled between the signal generator and the second common mode voltage circuit, the capacitor configured to generate a compensation artifact in the second common mode voltage in response to the compensation voltage change.
Aspect 9: The audio driver of aspect 8, wherein the audio driver further comprises a second integrator configured to integrate a second difference between a second integrator input signal and the first common mode voltage to generate a second integrator output signal, wherein the second integrator output signal exhibits a second artifact in response to the voltage change in the first common mode voltage, wherein the comparator is configured to generate a second pulse width modulated signal based on a difference between the second integrator output signal and the second common mode voltage.
Aspect 10: A method of providing an audio signal to a speaker, comprising: integrating a difference between a first integrator input signal and a first common mode voltage to generate a first integrator output signal, wherein the audio signal is based on the first integrator output signal; generating a voltage change in the first common mode voltage in response to a change between a first supply voltage and a second supply voltage, wherein the voltage change in the first common mode voltage produces a first artifact in the first integrator output signal; and reducing an effect on the audio signal due to the first artifact.
Aspect 11: The method of aspect 10, wherein reducing the effect on the audio signal due to the first artifact comprises generating a first compensation artifact in the first integrator output signal, the first compensation artifact cancels at least a portion of the first artifact.
Aspect 12: The method of aspect 11, wherein generating the first compensation artifact comprises: generating a compensation voltage change substantially coincidental with and opposite to the voltage change in the first common mode voltage; and integrating the compensation voltage change to generate the first compensation artifact.
Aspect 13: The method of aspect 10, further comprising: integrating a difference between a second integrator input signal and the first common mode voltage to generate a second integrator output signal, wherein the audio signal is based on the second integrator output signal, wherein the voltage change in the first common mode voltage produces a second artifact in the second integrator output signal; and reducing an effect on the audio signal due to the second artifact.
Aspect 14: The method of aspect 13, wherein reducing the effect on the audio signal due to the second artifact comprises generating a second compensation artifact in the second integrator output signal, the second compensation artifact cancels at least a portion of the second artifact.
Aspect 15: The method of aspect 10, further comprising generating a first pulse width modulated signal based on a difference between the first integrator output signal and a second common mode voltage, wherein reducing the effect on the audio signal due to the first artifact comprises generating a compensation artifact in the second common mode voltage.
Aspect 16: The method of aspect 15, wherein generating the compensation artifact comprises integrating the voltage change in the first common mode voltage to generate the compensation artifact in the second common mode voltage.
Aspect 17: The method of aspect 15, wherein generating the compensation artifact comprises: generating a compensation voltage change substantially coincidental with and the same as the voltage change in the first common mode voltage; and integrating the compensation voltage change to generate the compensation artifact.
Aspect 18: The method of aspect 15, further comprising: integrating a difference between a second integrator input signal and the first common mode voltage to generate a second integrator output signal, wherein the audio signal is based on the second integrator output signal, wherein the voltage change in the first common mode voltage produces a second artifact in the second integrator output signal; and reducing an effect on the audio signal due to the second artifact.
Aspect 19: The method of aspect 18, further comprising generating a second pulse width modulated signal based on a difference between the second integrator output signal and a second common mode voltage, wherein the compensation artifact in the second common mode voltage reduces the effect on the audio signal due to the second artifact.
Aspect 20: An apparatus, comprising: a first integrator including a signal input, a common mode input, and an output; a second integrator including a signal input, a common mode input, and an output; a comparator including a first signal input coupled to the output of the first integrator, a second signal input coupled to the second output of the second integrator, and a common mode input; and a capacitor coupled to the common mode input of the comparator.
Aspect 21: The apparatus of aspect 18, wherein the capacitor is coupled between the common mode inputs of the first and second integrators and the common mode input of the comparator.
Aspect 22: The apparatus of aspect 18, wherein the capacitor is coupled between a signal generator and the common mode input of the comparator.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An audio driver for generating an audio signal, comprising:
a first common mode voltage circuit configured to generate a first common mode voltage based on a selected one of a first supply voltage or a second supply voltage, wherein the first supply voltage is greater than the second supply voltage, wherein the first common mode voltage exhibits a voltage change in response to switching between the first supply voltage and the second supply voltage;
a first integrator configured to integrate a first difference between a first integrator input signal and the first common mode voltage to generate a first integrator output signal, wherein the audio signal is based on the first integrator output signal, wherein the first integrator output signal exhibits a first artifact in response to the voltage change in the first common mode voltage; and
an artifact reduction circuit configured to reduce an effect on the audio signal due to the first artifact.

2. The audio driver of claim 1, wherein the artifact reduction circuit is configured to generate a first compensation artifact to reduce the first artifact.

3. The audio driver of claim 2, wherein:
the first integrator comprises:
a first integrator amplifier including a first input configured to receive the first integrator input signal, a second input configured to receive the first common mode voltage, and an output configured to generate the first integrator output signal; and
a first capacitor coupled between the output and the first input of the first integrator amplifier;
wherein the artifact reduction circuit comprises:
a signal generator configured to generate a compensation voltage change substantially coincidental with and opposite to the voltage change in the first common mode voltage; and
a second capacitor configured to generate the first compensation artifact at the output of the first integrator in response to the compensation voltage change.

4. The audio driver of claim 3, wherein the audio driver further comprises a second integrator configured to integrate a second difference between a second integrator input signal and the first common mode voltage to generate a second integrator output signal, wherein the audio signal is based on the second integrator output signal, wherein the second integrator output signal exhibits a second artifact in response to the voltage change in the first common mode voltage, wherein the artifact reduction circuit is configured to generate a second compensation artifact to reduce the second artifact.

5. The audio driver of claim 4, wherein the second integrator comprises:
a second integrator amplifier including a first input configured to receive the second integrator input signal, a second input configured to receive the first common mode voltage, and an output configured to generate the second integrator output signal; and
a third capacitor coupled between the output and the first input of the second integrator amplifier;
wherein the artifact reduction circuit further comprises a fourth capacitor configured to generate the second compensation artifact at the output of the second integrator in response to the compensation voltage change.

6. The audio driver of claim 1, further comprising:
a second common mode voltage circuit configured to generate a second common mode voltage; and
a comparator configured to generate a first pulse width modulated signal based on a difference between the first integrator output signal and the second common mode voltage;
wherein the artifact reduction circuit comprises a capacitor coupled between the first common mode voltage circuit and the second common mode voltage circuit, the capacitor configured to generate a compensation artifact in the second common mode voltage in response to the voltage change in the first common mode voltage.

7. The audio driver of claim 6, wherein the audio driver further comprises a second integrator configured to integrate a second difference between a second integrator input signal and the first common mode voltage to generate a second integrator output signal, wherein the second integrator output signal exhibits a second artifact in response to the voltage change in the first common mode voltage, wherein the comparator is configured to generate a second pulse width modulated signal based on a difference between the second integrator output signal and the second common mode voltage.

8. The audio driver of claim 1, further comprising:
a second common mode voltage circuit configured to generate a second common mode voltage; and
a comparator configured to generate a first pulse width modulated signal based on a difference between the first integrator output signal and the second common mode voltage;
wherein the artifact reduction circuit comprises:
a signal generator configured to generate a compensation voltage change substantially coincidental with and the same as the voltage change in the first common mode voltage; and
a capacitor coupled between the signal generator and the second common mode voltage circuit, the capacitor configured to generate a compensation artifact in the second common mode voltage in response to the compensation voltage change.

9. The audio driver of claim 8, wherein the audio driver further comprises a second integrator configured to integrate a second difference between a second integrator input signal and the first common mode voltage to generate a second integrator output signal, wherein the second integrator output signal exhibits a second artifact in response to the voltage change in the first common mode voltage, wherein the comparator is configured to generate a second pulse width modulated signal based on a difference between the second integrator output signal and the second common mode voltage.

10. A method of providing an audio signal to a speaker, comprising:
integrating a difference between a first integrator input signal and a first common mode voltage to generate a first integrator output signal, wherein the audio signal is based on the first integrator output signal;
generating a voltage change in the first common mode voltage in response to a change between a first supply voltage and a second supply voltage, wherein the voltage change in the first common mode voltage produces a first artifact in the first integrator output signal; and
reducing an effect on the audio signal due to the first artifact.

11. The method of claim 10, further comprising:
integrating a difference between a second integrator input signal and the first common mode voltage to generate a second integrator output signal, wherein the audio signal is based on the second integrator output signal, wherein the voltage change in the first common mode voltage produces a second artifact in the second integrator output signal; and
reducing an effect on the audio signal due to the second artifact.

12. The method of claim 11, wherein reducing the effect on the audio signal due to the second artifact comprises generating a second compensation artifact in the second integrator output signal, the second compensation artifact cancels at least a portion of the second artifact.

13. The method of claim 10, further comprising generating a first pulse width modulated signal based on a difference between the first integrator output signal and a second common mode voltage, wherein reducing the effect on the audio signal due to the first artifact comprises generating a compensation artifact in the second common mode voltage.

14. The method of claim 13, wherein generating the compensation artifact comprises integrating the voltage change in the first common mode voltage to generate the compensation artifact in the second common mode voltage.

15. The method of claim 13, wherein generating the compensation artifact comprises:
generating a compensation voltage change substantially coincidental with and the same as the voltage change in the first common mode voltage; and
integrating the compensation voltage change to generate the compensation artifact.

16. The method of claim 13, further comprising:
integrating a difference between a second integrator input signal and the first common mode voltage to generate a second integrator output signal, wherein the audio signal is based on the second integrator output signal, wherein the voltage change in the first common mode voltage produces a second artifact in the second integrator output signal; and
reducing an effect on the audio signal due to the second artifact.

17. The method of claim 16, further comprising generating a second pulse width modulated signal based on a difference between the second integrator output signal and a second common mode voltage, wherein the compensation artifact in the second common mode voltage reduces the effect on the audio signal due to the second artifact.

18. An apparatus, comprising:
a first integrator including a signal input, a common mode input, and an output;
a second integrator including a signal input, a common mode input, and an output;
a comparator including a first signal input coupled to the output of the first integrator, a second signal input coupled to the second output of the second integrator, and a common mode input; and
a capacitor coupled to the common mode input of the comparator.

19. The apparatus of claim 18, wherein the capacitor is coupled between the common mode inputs of the first and second integrators and the common mode input of the comparator.

20. The apparatus of claim 18, wherein the capacitor is coupled between a signal generator and the common mode input of the comparator.
